(19) United States
(12) Patent Application Publication
(10) Pub. No.: US 2008/0178923 A1
(43) Pub. Date: Jul. 31, 2008

(54) Power generation diode module in roof tile

(75) Inventor: Henry Hu, Kwei Shan Shiang (TW)

Correspondence Address: TROXELL LAW OFFICE PLLC, SUITE 1404, 5205 LEESBURG PIKE, FALLS CHURCH, VA, 22041, US

(73) Assignee: LUCKY POWER TECHNOLOGY CO., LTD.

(21) Appl. No.: 11/699,069

(22) Filed: Jan. 29, 2007

(51) Int. Cl. H01L 31/02

(52) U.S. Cl. 136/244

(57) ABSTRACT

A power generation diode module adapted in a roof tile; the module containing a substrate, multiple GaAs chips being disposed on the substrate, each GaAs chip is disposed with a package; sun light being irradiated into those packages where to be refracted, converged inter the GaAs chip to convert light source into electric power before being transmitted from the substrate to a power consumption object in a house built up with multiple roof tiles.

### BACKGROUND OF THE INVENTION

(a) Field of the Invention

The present invention is related to a power generation diode module, and more particularly, to one that is adapted in a roof tile serving power source for the power consumption objects in the house built with the roof tiles.

(b) Description of the Prior Art

While we enjoy extremely convenient and civilized environment thanks to the highly developed world by man in recent years, we are expanding the survival rights of all living creatures on the earth. For example, disappearance of the ozone layer exposes us to the hazardous invasion of UV; the hole in the ozone layer contributes to the abnormal temperature rise of the earth including snowing in June and other bizarre weather conditions. Therefore, all the living creatures have to get use to and sustain those consequences man is blamed for. Even worse, ignorance with correcting actions would bring disasters to our children for generations to come, certainly the last thing we at the present generation would like to see.

For such a long time, we consume power supplied by large-scale power generation plants essentially operating on fossils and nuclear energy as primary fuels. More R&D efforts are inputted in searching for other power generation alternatives including horizontal shaft up-scaling wind velocity generation, solar energy generation, geodetic thermal generation, and tidal generation particularly in coping with oil crises and answering the environmental awareness. However, all these alternatives are prevented from being provided in a compact form or even commercialized due to limitations from the natural environment or cost efficiency.

### SUMMARY OF THE INVENTION

The primary purpose of the present invention is to provide a power generation diode module adapted in a roof tile to serve power source for power consumption objects in the house built up with the roof tiles.

To achieve the purpose, a power generation diode module of the present invention includes a substrate, multiple GaAs chips and a package. P(positive)-area and n(negative)-area are separately provided on the substrate to achieve electric connection respectively with positive and negative electrode layers of each GaAs chip; both of the positive and negative electrode layers are respectively connected to positive and negative output points; and those multiple packages are disposed on the substrate corresponding to each GaAs chip.

When the sun irradiates into those packages where the streams of light are converged due to refraction into GaAs chips to convert photo energy into electric power, which in turn is outputted through those positive and negative output points on the substrate to a power consumption objects. The power generation diode module is disposed in a roof tile to serve power source for power consumption objects in a house built up with roof tiles each containing the power generation diode module.

### BRIEF DESCRIPTION OF THE DRAWINGS

FIG. 1 is a schematic view showing a construction of a connection between power generation diode module of the present invention and a power consumption object.

FIG. 2 is a schematic view showing a construction of the power generation diode module of the present invention.

FIG. 3 is a schematic view showing a construction to absorb light source in the power generation diode module of the present invention.

FIG. 4 is a perspective view showing a roof tile of the present invention.

FIG. 5 is a schematic view showing a construction of the roof tile of the present invention.

FIG. 6 is a perspective view showing a construction of multiple roof tiles of the present invention in building up a house.

FIG. 7 is a schematic view showing another construction of a connection between the power generation diode module of the present invention and a power consumption object.

### DETAILED DESCRIPTION OF THE PREFERRED EMBODIMENTS

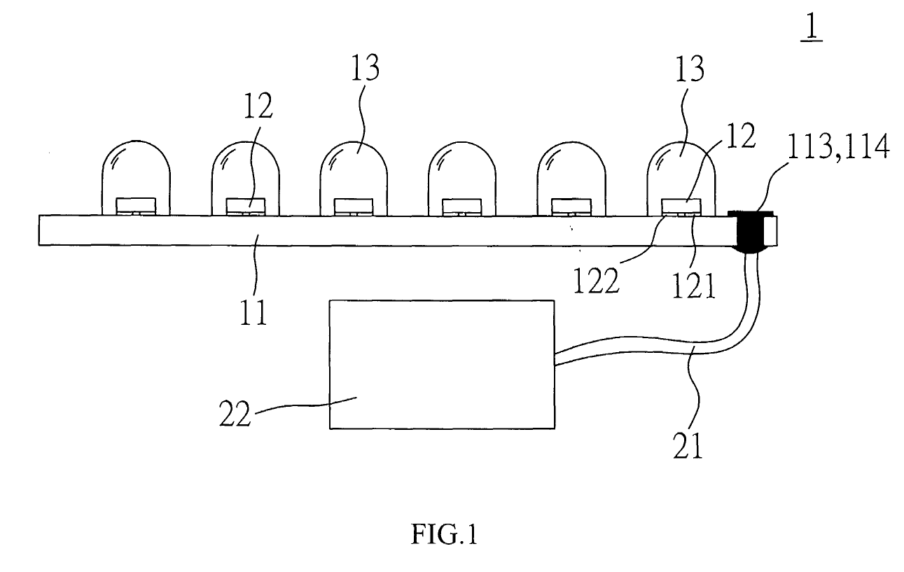

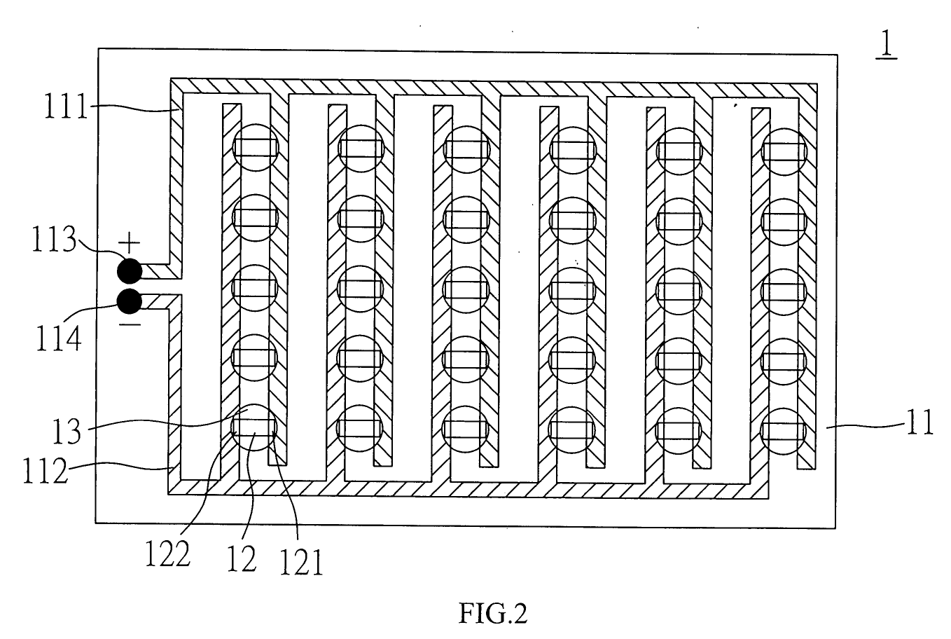

Referring to FIGS. 1, 2, and 3, a power generation diode module 1 contained in a roof tile includes a substrate 11 (e.g., a circuit board) separately provide with a p-area 111 and an n-area 112 thereon; and both of the p-area 111 and the n-area 112 are respectively connected to a positive electrode output point 113 and a negative electrode output point 114.

Multiple GaAs chips 12 are provided on the substrate 11 with each GaAs chip 12 disposed with a positive electrode layer 121 and a negative electrode layer 122 to respectively achieve electric connection with the positive and the negative electrode areas 111, 112.

Multiple packages 13 are provided on the substrate 11 at where correspond to each GaAs chip and each package 13 is related to a glass mask with low Fe (ferrum) containment.

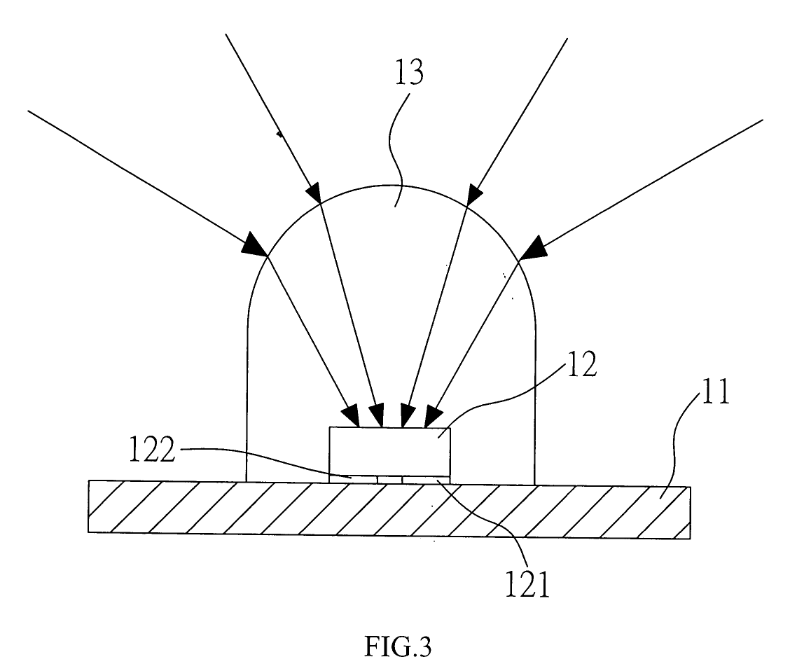

In practice, when sunlight or stream of light from other source as illustrated in FIG. 3 is eradiated into those packages 13, it is refracted to converge and eradiate the light source into the GaAs chip 12 where the light source to be converted into electric power. The electric power passes through both of the positive and the negative electrode layers 121, 122 on the GaAs chip and is outputted from both positive and negative electrode output points 113, 114 to connect to a power consumption object 22 by means of a conductor 21 to complete power transmission to the power consumption object 22.

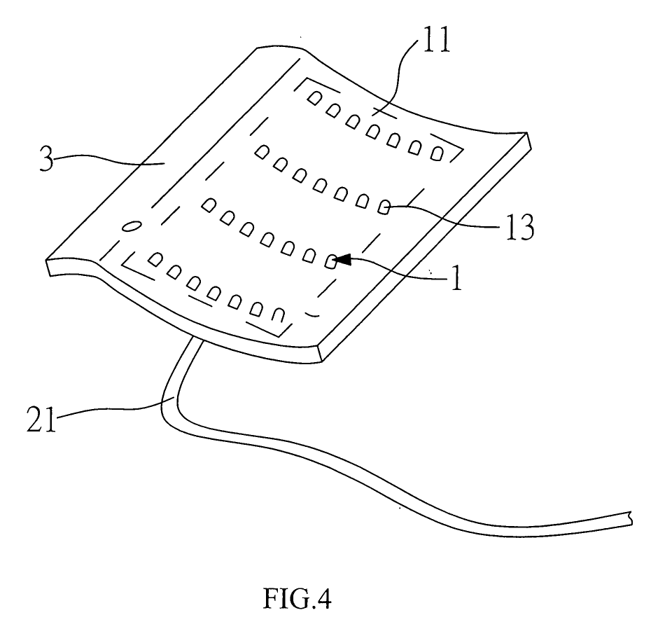

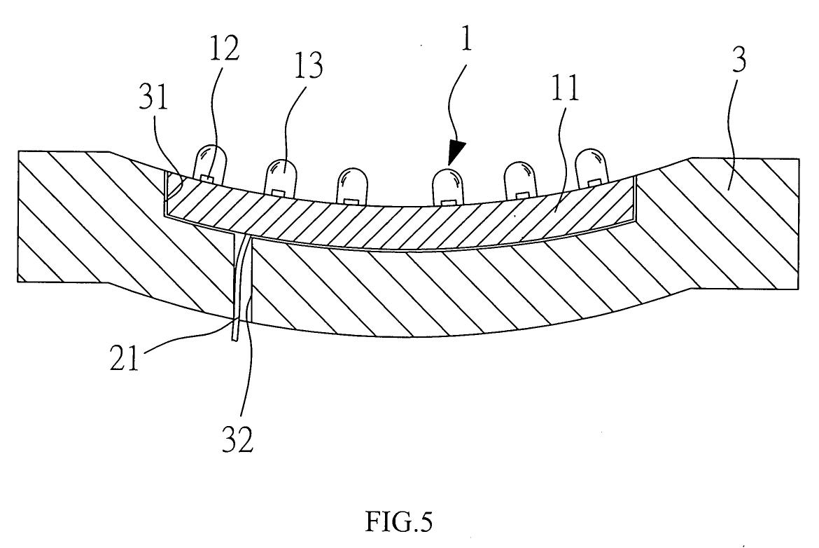

Furthermore, the power generation diode module 1 of the present invention is adapted in a roof tile 3 as illustrated in FIGS. 4 and 5. Wherein, an open slot 31 is provided to the tile 3 to accommodate the power generation diode module 1; the power generation diode module 1 also contains the substrate 11, multiple GaAs chips 12 and multiple packages 13 with those packages 13 exposed out of the surface of the tile 3; and a guide channel 32 connecting through the opening slot 31 is disposed to the tile 3 with the guide channel 32 further penetrating through the lower surface of the tile 3 to allow mounting of a conductor 21.

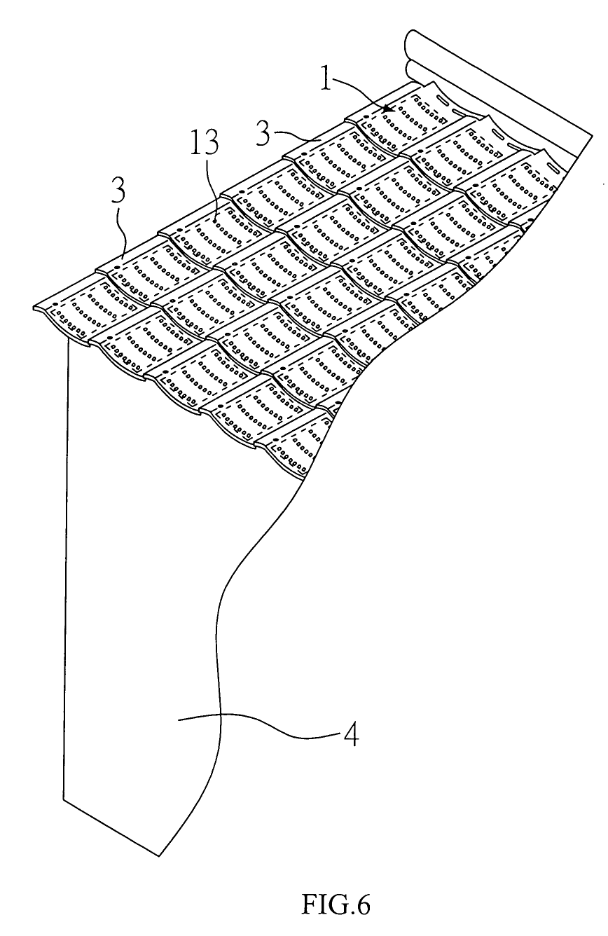

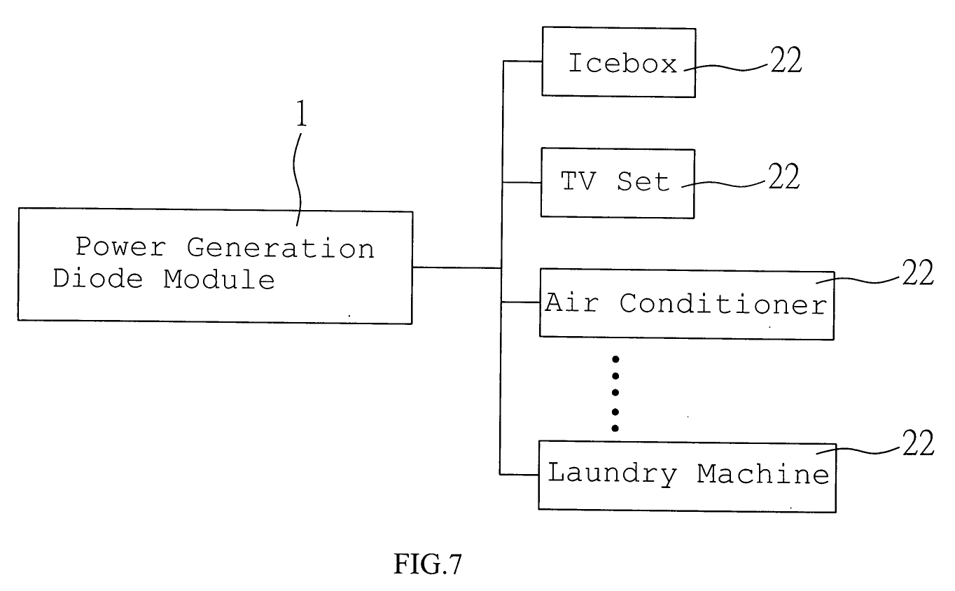

Once multiple tiles are paved on a roof of a house 4 as illustrated in FIG. 6, those packages 13 in the power generation diode module refract the stream of light to converge and irradiate light source into those GaAs chips 12 to convert the light source into electric power. The electric power so converted is then transmitted through the conductor 21 connected to those positive and negative electrode output points 113, 114 on the substrate 11 to the power consumption object 22 (e.g., icebox, TV set, air conditioner, laundry machine). As illustrated in FIG. 7, power to be consumed in daily life is supplied by the power generation diode module of the present invention thus to save energy consumption, comply with environmental requirements, and facilitate converging light streams through those packages in the power generation diode module to further improve efficiency of light source conversion.

The prevent invention provides an improved structure of a power generation diode module adapted in a roof tile, and the application for a utility patent is duly filed accordingly. However, it is to be noted that the preferred embodiments disclosed in the specification and the accompanying drawings are not limiting the present invention; and that any construction, installation, or characteristics that is same or similar to that of the present invention should fall within the scope of the purposes and claims of the present invention.

I claim:

1. A power generation diode module includes a substrate separately provided thereon a positive electrode area and a negative electrode area respectively connected to a positive electrode output point and a negative electrode output point; multiple GaAs chips also provided on the substrate with each chip disposed with a positive electrode layer and a negative electrode layer to respectively achieve electric connection with the positive electrode area and the negative electrode area; and multiple packages disposed on the substrate at where correspond to each GaAs chip.

2. The power generation diode module as claimed in claim 1, wherein the substrate relates to a circuit board.

3. The power generation diode module as claimed in claim 1, wherein each of those packages is related to a glass mask with low Fe containment.

4. The power generation diode module as claimed in claim 1, wherein both of the positive and the negative electrode output points are connected to a power consumption object by means of a conductor.

5. A roof tile containing the power generation diode module includes the power generation diode module as claimed in claim 1, the power generation diode module being built in the roof tile; those packages of the power generation diode module being exposed out of the roof tile; and an opening slot being disposed to the roof tile to accommodate the power generation diode module.

6. The roof tile containing the power generation diode module as claimed in claim 5, wherein the substrate relates to a circuit board.

7. The roof tile containing the power generation diode module as claimed in claim 5, wherein each of those packages is related to a glass mask with low Fe containment.

8. The roof tile containing the power generation diode module as claimed in claim 5, wherein both of the positive and the negative electrode output points are connected to a power consumption object by means of a conductor.

9. The roof tile containing the power generation diode module as claimed in claim 8, wherein a guide channel connecting through the opening slot is disposed to the roof tile; and the guide channel penetrates through the lower surface of the roof tile to accommodate the mounting of the conductor.
